(19) United States
(12) Patent Application Publication
(10) Pub. No.: US 2007/0257375 A1
(43) Pub. Date: Nov. 8, 2007

(54) Increased interconnect density electronic package and method of fabrication

(76) Inventors: James P. Roland, Fort Collins, CO (US); Ray M. Parkhurst, Hillsboro, OR (US); Ashish Alawani, San Jose, CA (US); Marshall J. Maple, Cupertino, CA (US); Thu N. Nguyen, San Jose, CA (US)

Correspondence Address: Kathy Manke;Avago Technologies Limited, 4380 Ziegler Road, Fort Collins, CO, 80525, US

(21) Appl. No.: 11/415,705

(22) Filed: May 2, 2006

(51) Int. Cl. H01L 21/00

(52) U.S. Cl. 257/778; 438/108

(57) ABSTRACT

An electronic package. The electronic package includes an electronic component having a heat producing device, an attachment piece, and at least two attachment units. Each unit includes an attachment pillar having a mating surface, a solder layer formed on the mating surface, and an attachment pad located on the attachment piece. The pillar of each unit is attached to its unit attachment pad via its unit solder layer and is otherwise attached to the electronic component. One pillar at least partially covers the heat producing device. Prior to attachment of pillars to their associated unit pads, the unit solder layer of the pillar at least partially covering the heat producing device is patterned to cover less than its mating surface, and the pillar at least partially covering the heat producing device is thermally connected to the heat producing device and to its unit attachment pad via its unit solder layer.

### BACKGROUND

A current method of attaching integrated circuits, such as active radio frequency integrated circuits (RFIC), to printed circuit boards (PCBs) uses conducting pillars in a flip-chip configuration. The pillars typically comprise metallic pillars which extend from the circuit side of the integrated circuit. Attachment of the integrated circuit to the printed circuit board is effected by depositing a layer of solder onto the ends of the pillars, heating the solder to reflow it, flipping the integrated circuit over, placing the solder on the pillars in contact with metallic traces on the printed circuit board, and applying heat thereby again reflowing the solder. Subsequent cooling will then bond the pillars to the printed circuit board traces.

Various conducting pillars provide electrical interconnection between the integrated circuit and a path for heat transfer from heat producing active devices on the integrated circuit to the printed circuit board. To reduce the size of the integrated circuit chip it is desirable to place signal and cooling pillars as close as possible. However, spacing between the pillars is limited by the possibility of shorting between traces on the printed circuit board that mate with the pillars due to the flow of solder well beyond the projection of the surface of the pillars during the bonding process.

To reduce the occurrence of such shorting, process dependent design rules are specified which limit how close adjacent pillars can be to each other and which may result in the die being larger than it would be otherwise in order to accommodate pillar placement.

The situation just described is exacerbated when pillars with large differences in their diameter are used. For example, 75 micron diameter pillars can be used for signal pads and greater than 500 micron pillars can be used for cooling. Since the solder layer is the same thickness for large and for small pillars and since the die attached to the printed circuit board collapses to a distance that is smaller than the solder thickness, there is significantly more solder volume at the perimeter of larger pillars typically used for cooling than there is for smaller pillars typically used for signals after attachment which results in a reduced gap between the reflowed solder. Thus, a larger spacing is required between a large pillar and another pillar in order to eliminate electrical shorting between the pillars than between two smaller pillars.

### SUMMARY

In a representative embodiment, an electronic package is disclosed. The electronic package comprises an electronic component having a heat producing device, an attachment piece, and at least two attachment units. Each unit comprises an attachment pillar having a mating surface, a solder layer formed on the mating surface, and an attachment pad located on the attachment piece. The pillar of each unit is attached to its unit attachment pad via its unit solder layer and is otherwise attached to the electronic component. One pillar at least partially covers the heat producing device. Prior to attachment of pillars to their associated unit pads, the unit solder layer of the pillar at least partially covering the heat producing device is patterned to cover less than its mating surface, and the pillar at least partially covering the heat producing device is thermally connected to the heat producing device and to its unit attachment pad via its unit solder layer.

In another representative embodiment, another electronic package is disclosed. The electronic package comprises an electronic component having a heat producing device and a thermal distribution layer, an attachment piece, and at least two attachment units. The thermal distribution layer is thermally connected to and at least partially covers the heat producing device. Each unit comprises an attachment pillar having a mating surface, a solder layer formed on the mating surface, and an attachment pad located on the attachment piece. The pillar of each unit is attached to its unit attachment pad via its unit solder layer. The pillar of one of the units is attached to the thermal distribution layer. The pillar of each unit other than the unit having its unit pillar attached to the thermal distribution layer is otherwise attached to the electronic component, and the pillar attached to the thermal distribution layer is thermally connected to the thermal distribution layer and to its unit attachment pad via its unit solder layer.

In still another representative embodiment, a method for fabricating an electronic package is disclosed. The method comprises fabricating an electronic component having a heat producing device and adding at least two pillars to the electronic component. Each attachment pillar has a mating surface. The method further comprises adding a solder layer to the mating surface of each of the pillars and attaching the pillars to attachment pads on an attachment piece via their solder layers. One pillar at least partially covers the heat producing device. The solder layer added to the pillar at least partially covering the heat producing device is patterned to cover less than its mating surface. The pillar at least partially covering the heat producing device is thermally connected to the heat producing device and to the attachment pad to which that pillar is attached via its unit solder layer.

In yet another representative embodiment, another method for fabricating an electronic package is disclosed. The method comprises fabricating an electronic component having a heat producing device, adding a thermal distribution layer thermally connected to and at least partially covering the heat producing device, and adding at least two pillars to the electronic component. Each attachment pillar has a mating surface; one of the pillars is attached to the thermal distribution layer; and the pillars other than the pillar attached to the thermal distribution layer is otherwise attached to the electronic component. The method further comprises adding a solder layer to the mating surface of each of the pillars and attaching the pillars to attachment pads on an attachment piece via their solder layers. The pillar attached to the thermal distribution layer is thermally connected to the thermal distribution layer and to the attachment pad to which it is physically connected via its unit solder layer.

Other aspects and advantages of the representative embodiments presented herein will become apparent from the following detailed description, taken in conjunction with the accompanying drawings.

### BRIEF DESCRIPTION OF THE DRAWINGS

The accompanying drawings provide visual representations which will be used to more fully describe various representative embodiments and can be used by those skilled in the art to better understand them and their inherent advantages. In these drawings, like reference numerals identify corresponding elements.

FIG. 1A is a drawing of an electronic package prior to attachment of a component to an attachment piece via attachment pillars having solder layers.

FIG. 1B is a drawing of the electronic package of FIG. 1A after attachment of the electronic component to the attachment piece via attachment pillars having solder layers.

FIG. 1C is a drawing of the view in the direction A-A shown in FIG. 1A.

FIG. 2A is a drawing of another electronic package prior to attachment of the component to the attachment piece via attachment pillars having a selective solder layer as described in various representative embodiments.

FIG. 2B is a drawing of the electronic package of FIG. 2A after attachment of the electronic component to the attachment piece via attachment pillars having selective solder layer as described in various representative embodiments.

FIG. 2C is a drawing of the view in the direction 1B-1B shown in FIG. 2A.

FIG. 3 is a flow chart of a method for fabricating the electronic package of FIG. 2B.

FIG. 4A is a drawing of still another electronic package prior to attachment of the component to the attachment piece via attachment pillars and thermal distribution layers as described in various representative embodiments.

FIG. 4B is a drawing of the electronic package of FIG. 4A after attachment of the component to the attachment piece via attachment pillars and thermal distribution layers as described in various representative embodiments.

FIG. 5A is a drawing of yet another electronic package prior to attachment of the component to the attachment piece via attachment pillars and thermal distribution layers as described in various representative embodiments.

FIG. 5B is a drawing of the electronic package of FIG. 5A after attachment of the component to the attachment piece via attachment pillars and thermal distribution layers as described in various representative embodiments.

FIG. 6 is a flow chart of a method for fabricating the electronic package of FIG. 5B.

### DETAILED DESCRIPTION

As shown in the drawings for purposes of illustration, novel techniques are disclosed herein for attaching electronic components, which could be integrated circuits, such as active radio frequency integrated circuits (RFIC), or other electronic devices, to printed circuit boards (PCBs) or other items using conducting pillars in a flip-chip configuration. In one representative embodiment, an electronic package comprises an electronic component and a printed circuit board, wherein the component is attached to the printed circuit board via attachment pillars, wherein the pillars have a selectively deposited solder layer which is smaller in extent than the surface of the pillars. The pillars are typically metallic post like structures which extend from the circuit side of the electronic component. Attachment of the integrated circuit to the printed circuit board is effected by depositing a layer of solder onto the ends of the pillars, heating the solder to obtain a reflow, flipping the integrated circuit over, placing the solder on the pillars in contact with metallic traces on the printed circuit board, and applying heat which again reflows the solder. Subsequent cooling then bonds the pillars to the printed circuit board traces. In another representative embodiment, excessive solder flow caused by the placement of larger pillars for cooling of the heat producing device can be reduced by placing a thermal distribution layer directly over the heat producing device thereby reducing the required size of the pillars.

Previous techniques for such systems have used a solder layer that covers substantially all of the surface of the pillars that mate with conducting traces on the printed circuit board and have not employed conducting layers covering the heat producing devices on the electronic component. As such, the minimum allowed spacing between the pillars has been limited by the possibility of shorting between traces on the printed circuit board due to the flow of solder beyond the projection of the surface of the pillars during the bonding process. As such, the resultant die has often been larger than it would otherwise be in order to accommodate pillar placement.

In the following detailed description and in the several figures of the drawings, like elements are identified with like reference numerals.

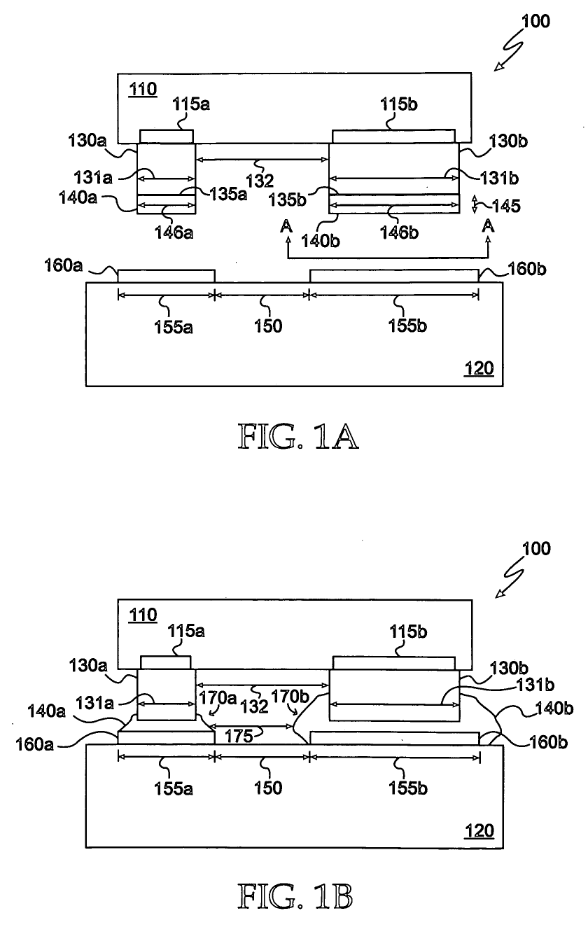

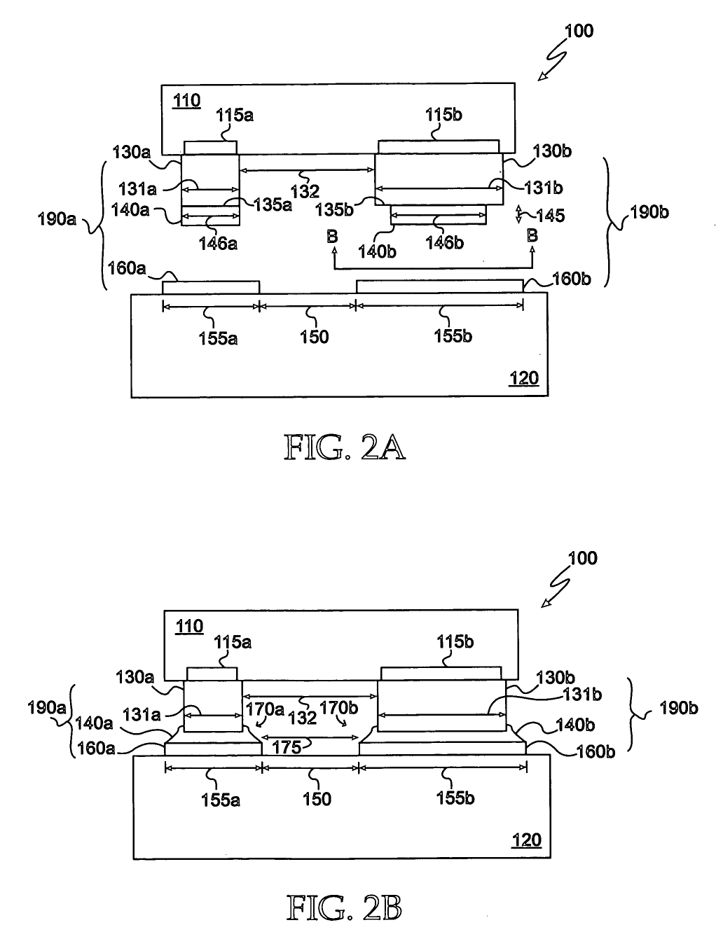

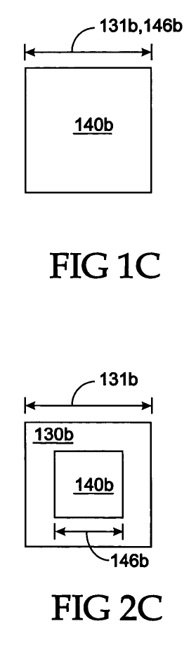

FIG. 1A is a drawing of an electronic package 100 prior to attachment of a component 110 to an attachment piece 120 via attachment pillars 130a,130b having solder layers 140a,140b. Attachment pillars 130a,130b are collectively referred to as attachment pillars 130, and solder layers 140a,140b are collectively referred to as solder layers 140. In FIG. 1A, the electronic package 100 comprises the component 110, the attachment piece 120, the pillars 130, and the solder layers 140. The attachment piece 120 could be a printed circuit board (PCB) 120, a ceramic substrate 120, a semiconductor substrate 120, a substrate 120, or other appropriate item. The component 110 is also referred to herein as the electronic component 110. In various representative embodiments, the electronic component 110 could be device 110, electronic device 110, integrated circuit 110, or integrated circuit chip 110 and may comprise one or more heat producing devices 115a,115b (collectively heat producing devices 115). The pillars 130a,130b on the electronic component 110 have pillar widths 131a,131b (collectively pillar widths 131) respectively and are separated from each other by a pillar space width 132. A pad space width 150 between attachment pads 160a,160b (collectively attachment pads 160) on the attachment piece 120 is typically large enough to prevent short circuits from occurring between adjacent attachment pads 160a,160b on the attachment piece 120. The attachment pads 160a,160b will themselves have pad widths 155a,155b (collectively pad widths 155). The solder layers 140 having a solder layer thickness 145 which for clarity of illustration is shown only on the right side of FIG. 1A and solder layer widths 146a,146b (collectively solder layer widths 146) are deposited, plated, or otherwise placed in a common operation onto mating surfaces 135a,135b (collectively mating surfaces 135) of pillars 130a,130b for subsequent use in bonding each of the pillars 130a,130b to matching attachment pads 160a,160b on the attachment piece 120. Note that in FIG. 1A the solder layer widths 146a,146b are equal to the pillar widths 131a,131b respectively of its associated pillar 130a,130b. This condition is shown in FIG. 1C where it also follows that each solder layer 140a,140b covers the mating surface 135a,135b of the associated pillar 130a,130b.

The solder layers 140 could comprise tin (Sn) or other appropriate material that is plated on top of the pillars 130. The pillars 130 could comprise copper (Cu) or other appropriate material and are used to attach the electronic component 110 to the attachment piece 120, The pillars 130 may perform the additional functions of electrically interconnecting the electronic component 110 to the attachment pads 160 on the attachment piece 120 and/or providing a path for heat transfer from heat producing devices 115 on the electronic component 110 to the attachment piece 120. The heat producing devices 115 could be resistors, active devices, or any other devices that produce heat and that are fabricated on or attached to the electronic component 110. The dimensions of the pillar space width 132 and the pad space width 150 are application dependent. However, the pillar space width 132 and the pad space width 150 will typically have minimum design values dictated primarily by an attempt to prevent shorting between attachment pads 160 on the attachment piece 120 due to the flow of solder beyond the projection of the mating surface 135 of the pillars 130 during the process of bonding the pillars 130 to the attachment piece 120. The attachment pads 160 may be conductive and may connect to conductive signal or other traces on the attachment piece 120.

FIG. 1B is a drawing of the electronic package 100 of FIG. 1A after attachment of the electronic component 110 to the attachment piece 120 via attachment pillars 130 having solder layers 140. In the attachment process, the temperature is raised such that solder in the solder layers 140 is reflowed onto the appropriate attachment pads 160 on the attachment piece 120. As the solder in the solder layer 140 is reflowed, the solder may expand beyond the confines of the attachment pads 160 on the attachment piece 120 as shown at representative locations 170a,170b (collectively locations 170) in FIG. 1B which may cause shorting between adjacent attachment pads 160 if the remaining gap 175 between reflowed solder from the adjacent pillars 130 is insufficient. This expansion of the solder beyond the confines of the attachment pads 160 may necessitate a larger than desired pad space width 150 between attachment pads 160 on the attachment piece 120 which in turn may force a larger pillar space width 132 than desired. The larger pillar space width 132 on the electronic component 110 may in turn cause the size of the electronic component 110 to increase with associated increase in the cost of the electronic component 110. This situation is especially pronounced for a larger pillar 130b as the solder from that solder layer 140b has a greater tendency to squeeze outside the boundary of the associated attachment pad 160b on the attachment piece 120 due to the greater volume of solder placed on the larger pillar 130b.

FIG. 1C is a drawing of the view in the direction A-A shown in FIG. 1A. In FIG. 1C, as indicated in FIG. 1A, the solder layer width 146b is approximately equal to the pillar width 131b with the other dimension of the solder layer 140b shown in FIG. 1C also equal to the other dimension of the pillar 130b shown in FIG. 1C. Thus, the solder layer 140b fully covers the mating surface 135b (not shown in FIG. 1C) of the pillar 130b. Similar statements can also be made for the smaller pillar 130a, its pillar width 131a, its solder layer 140a, its solder layer width 146a, and its mating surface 135a.

FIG. 2A is a drawing of another electronic package 100 prior to attachment of the component 110 to the attachment piece 120 via attachment pillars 130 having a selective solder layer 140 as described in various representative embodiments. The attachment piece 120 could be a printed circuit board (PCB) 120, a ceramic substrate 120, a semiconductor substrate 120, a substrate 120, or other appropriate item. In FIG. 2A, the electronic package 100 comprises the electronic component 110, the attachment piece 120, the pillars 130, and the solder layer 140. In various representative embodiments, the electronic component 110 could be device 110, electronic device 110, integrated circuit 110, or integrated circuit chip 110 and may comprise one or more heat producing devices 115. The pillars 130 on the electronic component 110 have pillar widths 131 and are separated from each other by a pillar space width 132. A pad space width 150 between attachment pads 160 on the attachment piece 120 is typically large enough to prevent short circuits from occurring between adjacent attachment pads 160 on the attachment piece 120. The attachment pads 160 will themselves have pad widths 155. The solder layers 140 having a solder layer thickness 145 which for clarity of illustration is shown only on the right side of FIG. 2A and solder layer widths 146 are deposited, plated, or otherwise placed in a common operation onto mating surfaces 135 of each pillar 130 for subsequent use in bonding the pillars 130 to matching attachment pads 160 on the attachment piece 120. Note that in FIG. 2A the pillar widths 131b is larger than the solder layer width 146b. This condition is shown in FIG. 2C wherein it is also indicated that solder layer 140b does not cover all of the mating surface 135b of the associated pillar 130b.

The solder layers 140 could comprise tin (Sn) or other appropriate material that is plated on top of the pillars 130. The pillars 130 could comprise copper (Cu) or other appropriate material and are used to attach the electronic component 110 to the attachment piece 120 and may perform the additional functions of electrically interconnecting the electronic component 110 to the attachment pads 160 on the attachment piece 120 and/or providing a path for heat transfer from heat producing devices 115 on the electronic component 110 to the attachment piece 120. The heat producing devices 115 could be resistors, active devices, or any other devices that produce heat and that are fabricated on or attached to the electronic component 110. The dimensions of the pillar space width 132 and the pad space width 150 are application dependent. However, the pillar space width 132 and the pad space width 150 will typically have minimum design values dictated primarily by an attempt to prevent shorting between attachment pads 160 on the attachment piece 120. In the case of FIG. 2A, potential shorting due to the flow of solder beyond the projection of the mating surface 135 of the pillars 130 during the process of bonding the pillars 130 to the attachment piece 120 is reduced over that of FIGS. 1A-1B. The attachment pads 160 may be conductive and may connect to conductive signal or other traces on the attachment piece 120.

Each attachment unit 190 shown in FIG. 2A separately as unit 190a and unit 190b comprises one pillar 130, the solder layer 140 attached to that pillar 130, and the attachment pad 160 to which that pillar 130 is or will be attached via the solder layer 140 of that pillar 130.

FIG. 2B is a drawing of the electronic package 100 of FIG. 2A after attachment of the electronic component 110 to the attachment piece 120 via attachment pillars 130 having selective solder layer 140 as described in various representative embodiments. In the attachment process, the temperature is raised such that solder in the solder layer 140 is reflowed onto the appropriate attachment pads 160 on the attachment piece 120. As the solder in the solder layer 140 is reflowed, the solder typically expands outward. But, in the representative embodiment of FIG. 2B, the distance that the solder extends beyond the pillars 130 is less than that of FIG. 1B with the resultant smaller gap 175 in FIG. 2B relative to that of FIG. 1B for the same pillar space width 132. Thus, the potential for shorting between adjacent attachment pads 160 due to the reflow of solder between adjacent pillars 130 is reduced. This confinement of the solder within the perimeter of the attachment pads 160 can result in a smaller required pad space width 150 between attachment pads 160 of the attachment piece 120 than necessary for the electronic package 100 of FIGS. 1A-1B. This in turn can result in a smaller and more desirable pillar space width 132 than for the electronic package 100 of FIGS. 1A-1B. The smaller pillar space width 132 on the electronic component 110 of FIGS. 2A-2B may in turn cause the size of the electronic component 110 to be smaller with associated lower cost for the electronic component 110 of FIGS. 2A-2B than the electronic component 110 of FIGS. 1A-1B.

Each attachment unit 190 shown in FIG. 2B separately as unit 190a and unit 190b comprises one pillar 130, the solder layer 140 attached to that pillar 130, and the attachment pad 160 to which that pillar 130 is or will be attached via the solder layer 140 of that pillar 130.

FIG. 2C is a drawing of the view in the direction B-B shown in FIG. 2A. In FIG. 2C, as indicated in FIG. 2A, the solder layer width 146b is less than the pillar width 131b with the other dimension of the solder layer 140b shown in FIG. 2C also less than the other dimension of the pillar 130b shown in FIG. 2C. Thus, the solder layer 140b as deposited does not fully cover the mating surface 135b of the pillar 130b. Following solder layer 140 deposition, the solder is reflowed resulting in covering the pillars 130 to the dimensions of the pillar widths 131. The thickness of the solder layer 140 for any given pillar 130 is now dependent upon the as deposited solder layer width 146 for that pillar 130 and is thinner than it would otherwise be had the solder layer width 146 been the same as the pillar width 131. The solder 140 is reflowed at this point in order to form a spherical surface on the solder 140. If the solder 140 is not reflowed at this point, but only when making the attachment, voids can be trapped between the solder 140 and the attachment pads 160.

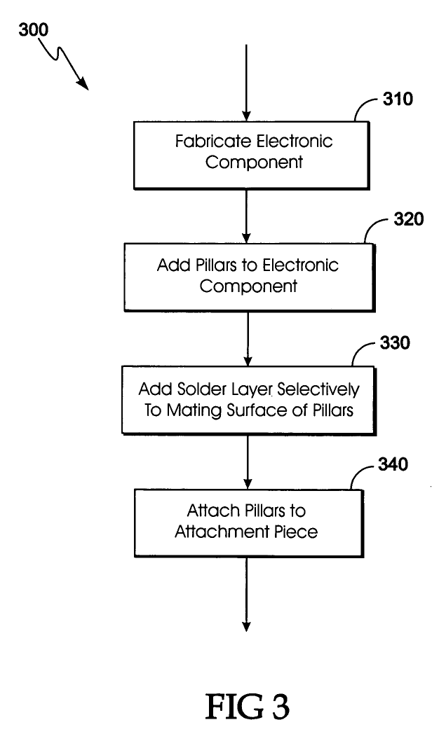

FIG. 3 is a flow chart of a method 300 for fabricating the electronic package 100 of FIG. 2B. In block 310, the electronic component 110 is fabricated. Such fabrication could include standard integrated circuit processing methods. Block 310 then transfers control to block 320.

In block 320, the pillars 130 are added to the electronic component 110. The pillars 130 can be fabricated using well known technologies such as photolithography and deposition. As an example, a seed layer which could comprise sputtering 1,000 angstroms of titanium (Ti) and 4,000 angstroms of copper (Cu) could be first deposited on the electronic component 110; a layer of photoresist could be applied to the electronic component 110; the photoresist could be exposed via a photomask having the appropriate pattern; and the photoresist could be subsequently developed to appropriately pattern the photoresist to the pattern of the pillars 130. The pillars 130 could then be formed by electroplating approximately 30-125 microns thick copper or other appropriate material. Block 320 then transfers control to block 330.

In block 330, the solder layer 140 is added selectively to the pillars 130, for example, as shown in FIGS. 2A and 2C. In FIG. 2C, as was indicated in FIG. 2A, the solder layer width 146 is less than the pillar width 131 with the other dimension of the solder layer 140 shown in FIG. 2C also less than the other dimension of the pillar 130 shown in FIG. 2C. Thus, as formed the solder layer 140 does not fully cover the mating surface 135 of the pillar 130. The selectively added solder layer 140 can be fabricated using well known technologies such as deposition. As an example, a layer of photoresist approximately 20-40 microns thick could be spun or otherwise applied to the electronic component 110; the photoresist could be exposed via a photomask having the appropriate pattern; the photoresist could be subsequently developed to appropriately pattern the photoresist to the pattern of the solder layer 140; a layer of a solder material such as tin of approximately 20 microns thick or other appropriate material could be plated onto the electronic component 110; and then stripping the photoresist. In alternative approach, a layer of a solder material such as tin of approximately 20 microns thick or other appropriate material could be deposited onto the electronic component 110; a layer of photoresist approximately 20-40 microns thick could be applied to the electronic component 110; the photoresist could be exposed via a photomask having the appropriate pattern; the photoresist could be subsequently developed to appropriately pattern the photoresist to the pattern of the solder layer 140; the solder layer 140 could be etched; and then the photoresist could be stripped. Regardless of the method used to put the solder 140 in place, the solder 140 could be reflowed at this point in order to form a spherical surface on the solder 140, thereby reducing the potential for voids trapped between the solder 140 and the attachment pads 160 during the attachment process. Block 330 then transfers control to block 340.

In block 340, the pillars 130 previously added to the electronic component 110 are attached to the attachment piece 120. The attachment piece 120 could be a printed circuit board (PCB) 120, a ceramic substrate 120, a semiconductor substrate 120, a substrate 120, or other appropriate item. Such attachment could be effected by adding a flux to the solder, placing the solder layer 140 in contact with the attachment pads 160 on the attachment piece 120, then applying heat such that the solder in the solder layer 140 reflows, allowing the solder to cool while maintaining contact between the pillars 130 and the attachment pads 160 via the solder, and finally cleaning the solder. Block 340 then terminates the process.

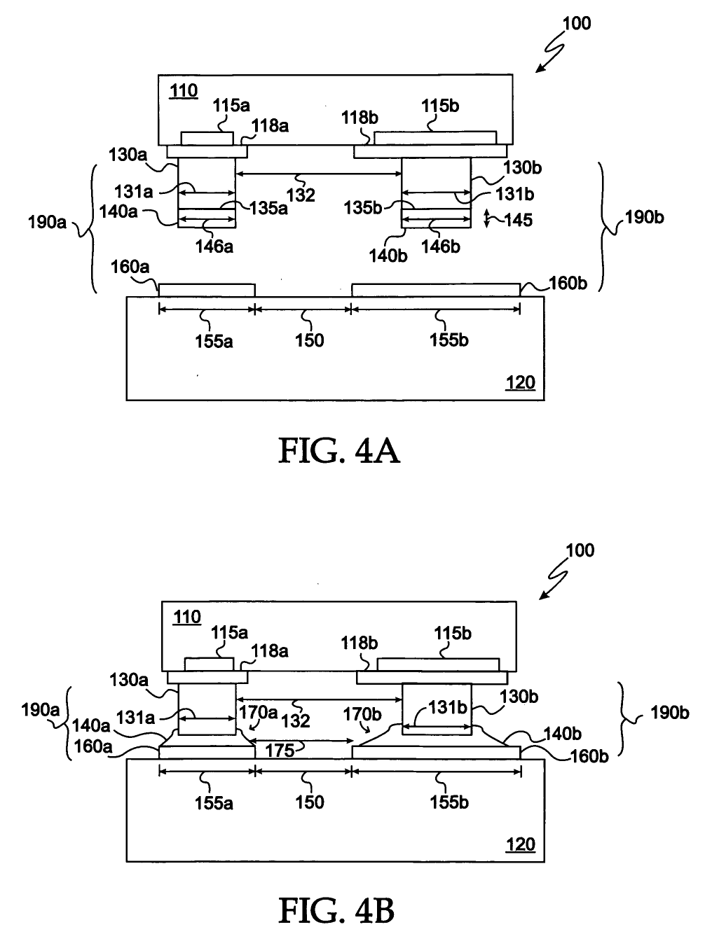

FIG. 4A is a drawing of still another electronic package 100 prior to attachment of the component 110 to the attachment piece 120 via attachment pillars 130 and thermal distribution layers 118a,118b as described in various representative embodiments. The attachment piece 120 could be a printed circuit board (PCB) 120, a ceramic substrate 120, a semiconductor substrate 120, a substrate 120, or other appropriate item. In FIG. 4A, the electronic package 100 comprises the electronic component 110, the attachment piece 120, the pillars 130, and the solder layer 140. In various representative embodiments, the electronic component 110 could be device 110, electronic device 110, integrated circuit 110, or integrated circuit chip 110 and may comprise one or more heat producing devices 115 and one or more thermal distribution layers 118. The pillars 130a,130b of FIG. 4A (and FIG. 4B) are separated from each other by a pillar space width 132. Note that in FIG. 4A (and FIG. 4B) the edges of the pillar 130b are not coincident with the edges of the heat producing device 115b. Nor, are the edges of the pillar 130a coincident with the edges of the heat producing device 115a. Thermal distribution layers 118 enable the effective removal of heat from heat producing devices 115 using pillars 130 having edges internal to the edges of the heat producing devices 115 on one or more sides of the pillars 130. The choice of whether or not to place an edge of a given pillar 130, that is in thermal contact with a thermal distribution layer 118 that covers a heat producing device 115, internal to the heat producing device 115 on a particular side of the pillar 130 can be made based on the placement of adjacent pillars 130. If there is an adjacent pillar 130 on a particular side, it can be moved closer to the heat producing device 115 by restricting the edge of the pillar 130 on that side to lie internal to the edge of the heat producing device 115 on that side. Thus, even if the spacing between the pillars 130a,130b of FIG. 4A (and FIG. 4B) is the same as that between the pillars 130a,130b of FIGS. 1A-1B, the size of the electronic component 110 with associated reduction in the cost of the electronic component 110 can be reduced by use of thermal distribution layers 118 with appropriate restriction of one or more pillar 130 edges internal to the edges of the heat producing device 115 that it is over.

A pad space width 150 between attachment pads 160 on the attachment piece 120 is typically large enough to prevent short circuits from occurring between adjacent attachment pads 160 on the attachment piece 120. The attachment pads 160a,160b will themselves have respectively pad widths 155a,155b. Solder layers 140a,140b having solder layer thickness 145 and respectively solder layer widths 146a,146b are deposited, plated, or otherwise placed onto respectively mating surfaces 135a,135b of each of the pillars 130a,130b for subsequent use in bonding the pillars 130a,130b to their respective matching attachment pads 160a,160b on the attachment piece 120.

The solder layers 140a,140b could comprise tin (Sn) or other appropriate material that is plated on top of the pillars 130a,130b. The pillars 130a,130b could comprise copper (Cu) or other appropriate material and are used to attach the electronic component 110 to the attachment piece 120 and may perform the additional functions of electrically interconnecting the electronic component 110 to the attachment pads 160a,160b on the attachment piece 120 and/or providing a path for heat transfer from heat producing devices 115 on the electronic component 110 to the attachment piece 120. The heat producing devices 115 could be resistors, active devices, or any other devices that produce heat and that are fabricated on or attached to the electronic component 110. The dimensions of the pillar space widths 132a,132b and the pad space widths 150a,150b are application dependent. However, the pillar space width 132 and the pad space width 150 will typically have minimum design values dictated primarily by an attempt to prevent shorting between attachment pads 160a,160b on the attachment piece 120 due to the flow of solder beyond the projection of the mating surfaces 135a,135b of the pillars 130a,130b during the process of bonding the pillars 130a,130b to the attachment piece 120. The attachment pads 160a,160b may be conductive and may connect to conductive signal or other traces on the attachment piece 120. The thermal distribution layers 118a,118b are placed over the heat producing devices 115a,115b and between the electronic component 110 and the pillars 130a,130b.

Each attachment unit 190 shown in FIG. 4A separately as unit 190a and unit 190b comprises one pillar 130, the solder layer 140 attached to that pillar 130, and the attachment pad 160 to which that pillar 130 is or will be attached via the solder layer 140 of that pillar 130.

FIG. 4B is a drawing of the electronic package 100 of FIG. 4A after attachment of the component 110 to the attachment piece 120 via attachment pillars 130 and thermal distribution layers 118a,118b as described in various representative embodiments. In the attachment process, the temperature is raised such that solder in the solder layers 140a,140b is reflowed onto the appropriate attachment pads 160a,160b on the attachment piece 120. As the solder in the solder layers 140a,140b is reflowed, the solder may expand beyond the confines of the attachment pads 160a,160b on the attachment piece 120 as shown at representative locations 170 in FIG. 4B which may cause shorting between adjacent attachment pads 160 if the remaining gap 175 between reflowed solder from the adjacent pillars 130a,130b is insufficient. However, for the embodiment of FIG. 4B, placement of the thermal distribution layers 118a,118b over the heat producing devices 115 reduces the necessity for larger pillars 130 resulting in less expansion of the solder beyond the confines of the attachment pads 160a,160b. As such, a smaller pad space width 150 between attachment piece 120 attachment pads 160a,160b can be accommodated which in turn may enable a smaller pillar space width 132. The smaller pillar space width 132 on the electronic component 110 may in turn enable the size of the electronic component 110 to be reduced with associated reduction in the cost of the electronic component 110.

Each attachment unit 190 shown in FIG. 4B separately as unit 190a and unit 190b comprises one pillar 130, the solder layer 140 attached to that pillar 130, and the attachment pad 160 to which that pillar 130 is or will be attached via the solder layer 140 of that pillar 130.

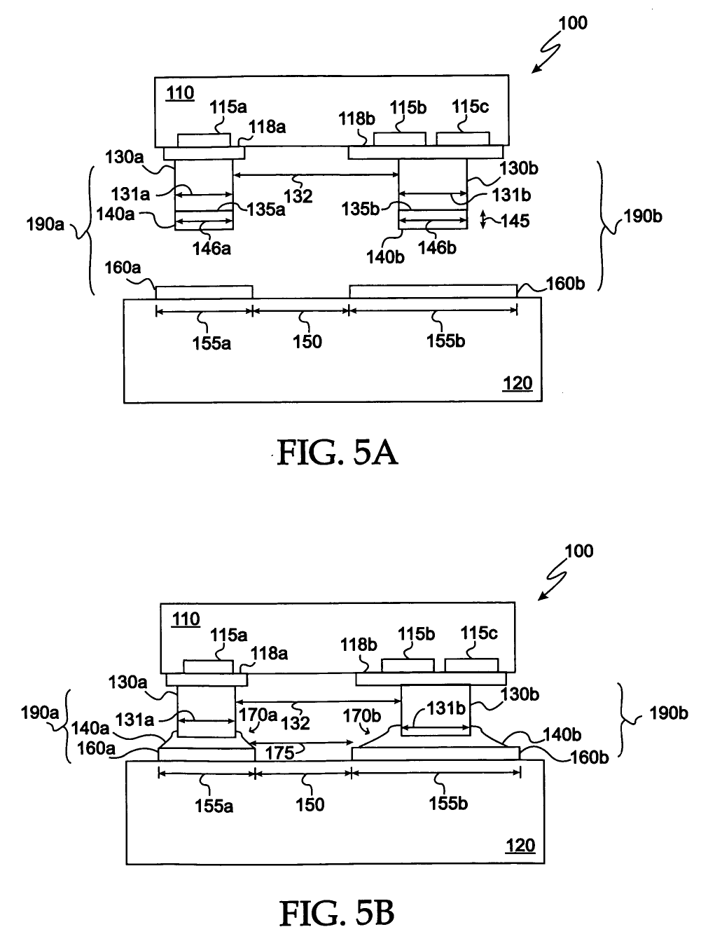

FIG. 5A is a drawing of yet another electronic package 100 prior to attachment of the component 110 to the attachment piece 120 via attachment pillars 130 and thermal distribution layers 118a,118b as described in various representative embodiments. The attachment piece 120 could be a printed circuit board (PCB) 120, a ceramic substrate 120, a semiconductor substrate 120, a substrate 120, or other appropriate item. In FIG. 5A, the electronic package 100 comprises the electronic component 110, the attachment piece 120, the pillars 130, and the solder layer 140. In various representative embodiments, the electronic component 110 could be device 110, electronic device 110, integrated circuit 110, or integrated circuit chip 110 and may comprise one or more heat producing devices 115 and one or more thermal distribution layers 118. Note that in FIGS. 5A-5B, one of the thermal distribution layers 118b covers multiple heat producing devices 115b,115c. The pillars 130a,130b of FIG. 5A (and FIG. 5B) are separated from each other by a pillar space width 132. As in FIGS. 4A and 4B the edges of the pillar 130b of FIG. 5A (and FIG. 5B) are not coincident with the outer edges of the heat producing devices 115b,115c. Nor, are the edges of the pillar 130a of FIG. 5A (and FIG. 5B) coincident with the edges of the heat producing device 115a. Thermal distribution layers 118 enable the effective removal of heat from heat producing devices 115 using pillars 130 having edges internal to the outer edges of the heat producing devices 115 on one or more sides of the pillars 130. The choice of where to place an edge of a given pillar 130 that is in thermal contact with a thermal distribution layer 118 that covers one or more heat producing devices 115 can be made based on the placement of adjacent pillars 130. If there is an adjacent pillar 130 on a particular side, it can be moved closer to one or more of the heat producing devices 115 by restricting the edge of the pillar 130 on that side which can lead to a reduction in the size of the electronic component 110 with associated reduction in the cost of the electronic component 110.

A pad space width 150 between attachment pads 160 on the attachment piece 120 is typically large enough to prevent short circuits from occurring between adjacent attachment pads 160 on the attachment piece 120. The attachment pads 160a,160b will themselves have respectively pad widths 155a,155b. Solder layers 140a,140b having solder layer thickness 145 and respectively solder layer widths 146a,146b are deposited, plated, or otherwise placed onto respectively mating surfaces 135a,135b of each of the pillars 130a,130b for subsequent use in bonding the pillars 130a,130b to their respective matching attachment pads 160a,160b on the attachment piece 120.

The solder layers 140a,140b could comprise tin (Sn) or other appropriate material that is plated on top of the pillars 130a,130b. The pillars 130a,130b could comprise copper (Cu) or other appropriate material and are used to attach the electronic component 110 to the attachment piece 120 and may perform the additional functions of electrically interconnecting the electronic component 110 to the attachment pads 160a,160b on the attachment piece 120 and/or providing a path for heat transfer from heat producing devices 115 on the electronic component 110 to the attachment piece 120. The heat producing devices 115 could be resistors, active devices, or any other devices that produce heat and that are fabricated on or attached to the electronic component 110. The dimensions of the pillar space widths 132a,132b and the pad space width 150a,150b are application dependent. However, the pillar space width 132 and the pad space width 150 will typically have minimum design values dictated primarily by an attempt to prevent shorting between attachment pads 160a,160b on the attachment piece 120 due to the flow of solder beyond the projection of the mating surfaces 135a,135b of the pillars 130a,130b during the process of bonding the pillars 130a,130b to the attachment piece 120. The attachment pads 160a,160b may be conductive and may connect to conductive signal or other traces on the attachment piece 120. The thermal distribution layer 118a is placed over the heat producing device 115a and between the electronic component 110 and the pillars 130a. Also, the thermal distribution layer 118b is placed over multiple heat producing devices 115b,115c and between the electronic component 110 and the pillar 130b.

Each attachment unit 190 shown in FIG. 5A separately as unit 190a and unit 190b comprises one pillar 130, the solder layer 140 attached to that pillar 130, and the attachment pad 160 to which that pillar 130 is or will be attached via the solder layer 140 of that pillar 130.

FIG. 5B is a drawing of the electronic package 100 of FIG. 5A after attachment of the component 110 to the attachment piece 120 via attachment pillars 130 and thermal distribution layers 118a,118b as described in various representative embodiments. In the attachment process, the temperature is raised such that solder in the solder layers 140a,140b is reflowed onto the appropriate attachment pads 160a,160b on the attachment piece 120. As the solder in the solder layers 140a,140b is reflowed, the solder may expand beyond the confines of the attachment pads 160a,160b on the attachment piece 120 as shown at representative locations 170 in FIG. 5B which may cause shorting between adjacent attachment pads 160 if the remaining gap 175 between reflowed solder from the adjacent pillars 130a,130b is insufficient. However as mentioned above, thermal distribution layers 118 enable the effective removal of heat from heat producing devices 115 using pillars 130 having edges internal to the outer edges of the heat producing devices 115 on one or more sides of the pillars 130. The choice of where to place an edge of a given pillar 130, that is in thermal contact with a thermal distribution layer 118 that covers one or more heat producing devices 115 can be made based on the placement of adjacent pillars 130. If there is an adjacent pillar 130 on a particular side, it can be moved closer to one or more of the heat producing devices 115 by restricting the edge of the pillar 130 on that side which can lead to a reduction in the size of the electronic component 110 with associated reduction in the cost of the electronic component 110.

Each attachment unit 190 shown in FIG. 5B separately as unit 190a and unit 190b comprises one pillar 130, the solder layer 140 attached to that pillar 130, and the attachment pad 160 to which that pillar 130 is or will be attached via the solder layer 140 of that pillar 130.

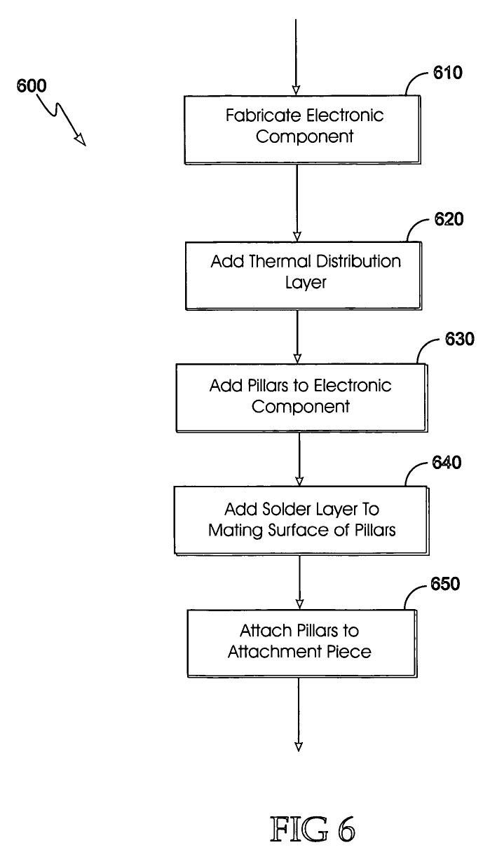

FIG. 6 is a flow chart of a method 600 for fabricating the electronic package 100 of FIG. 5B. In block 610, the electronic component 110 is fabricated. Such fabrication could include standard integrated circuit processing methods. Block 610 then transfers control to block 620.

In block 620, the thermal distribution layer 118 is added to the electronic component 110 wherein the thermal distribution layer 118 covers at least part of at least one of the heat producing devices 115. Adding the thermal distribution layer 118 could comprise (1) depositing a seed layer which could comprise sputtering 1,000 angstroms of titanium (Ti) plus approximately 4,000 angstroms of copper (Cu), (2) applying, exposing, and developing a layer of photoresist to appropriately pattern the thermal distribution layer 118 using a photoresist layer that is thicker than the thermal distribution layer 118 (approximately 2-50 microns) to be deposited, (3) depositing the thermal distribution layer 118 (approximately 2-40 microns of copper), and (4) stripping the photoresist. In an alternative process, the stripping of the current layer of photoresist can be omitted. Block 620 then transfers control to block 630.

In block 630, the pillars 130 are added to the electronic component 110. The pillars 130 can be fabricated using well known technologies such as photolithography and deposition. As an example, a layer of photoresist could be applied to the electronic component 110; the photoresist could be exposed via a photomask having the appropriate pattern; and the photoresist could be subsequently developed to appropriately pattern the photoresist to the pattern of the pillars 130. The pillars 130 could then be formed by depositing approximately 30-125 microns thick copper or other appropriate material. Block 630 then transfers control to block 640.

In block 640, the solder layer 140 is added to the pillars 130. The solder layer 140 can be added using well known technologies such as deposition. As an example, a layer of a solder material such as tin of approximately 20 microns thick or other appropriate material could be deposited onto the pillars 130 followed by stripping the photoresist and etching the seed layer. Block 640 then transfers control to block 650.

In block 650, the pillars 130 previously added to the electronic component 110 are attached to the attachment piece 120. The attachment piece 120 could be a printed circuit board (PCB) 120, a ceramic substrate 120, a semiconductor substrate 120, a substrate 120, or other appropriate item. Such attachment could be effected by adding a flux to the solder, placing the solder layer 140 in contact with the attachment pads 160 on the attachment piece 120, then applying heat such that the solder in the solder layer 140 reflows, allowing the solder to cool while maintaining contact between the pillars 130 and the attachment pads 160 via the solder, and finally cleaning the solder. Block 650 then terminates the process.

Advantages of the representative embodiments disclosed include the ability to reduce pillar space widths 132 which allows the attachment pads 160 to be placed closer together than existing methods which in turn allows the pillars 130 to be closer together resulting in a potential reduction in the size of the electronic component 110 with associated reduction in cost. In the embodiment of FIGS. 2A-2C, the pillars 130 and the solder layer 140 are added using two separate photolithographic steps which can use thinner photoresist permitting a finer pattern resolution with associated smaller geometries and smaller variations in the finished product.

In the embodiments of FIGS. 4A-4B and FIGS. 5A-5B, thermal distribution layers 118 are placed directly over the heat producing devices 115. Thermal distribution layers 118 enable the effective removal of heat from heat producing devices 115 using pillars 130 having edges internal to the outer edges of the heat producing device(s) 115 on one or more sides of the pillars 130. The choice of where to place an edge of a given pillar 130, that is in thermal contact with a thermal distribution layer 118 that covers one or more heat producing devices 115 can be made based on the placement of adjacent pillars 130. If there is an adjacent pillar 130 on a particular side, it can be moved closer to one or more of the heat producing devices 115 by restricting the edge of the pillar 130 on that side which can lead to a reduction in the size of the electronic component 110 with associated reduction in the cost of the electronic component 110.

The representative embodiments, which have been described in detail herein, have been presented by way of example and not by way of limitation. It will be understood by those skilled in the art that various changes may be made in the form and details of the described embodiments resulting in equivalent embodiments that remain within the scope of the appended claims.

What is claimed is:

1. An electronic package, comprising:
an electronic component having a heat producing device;
an attachment piece; and
at least two attachment units, wherein each unit comprises an attachment pillar having a mating surface, a solder layer formed on the mating surface, and an attachment pad located on the attachment piece, wherein the pillar of each unit is attached to its unit attachment pad via its unit solder layer and is otherwise attached to the electronic component, wherein one pillar at least partially covers the heat producing device, wherein prior to attachment of the pillars to their associated unit pads, the unit solder layer of the pillar at least partially covering the heat producing device is patterned to cover less than its mating surface, and wherein the pillar at least partially covering the heat producing device is thermally connected to the heat producing device and to its unit attachment pad via its unit solder layer.

2. The electronic package as recited in claim 1, wherein at least one pillar other than the pillar that at least partially covers the heat producing device has its mating surface smaller than the mating surface of the pillar that at least partially covers the heat producing device.

3. The electronic package as recited in claim 1, wherein at least one unit provides electrical connection between the electronic component and the attachment piece.

4. The electronic package as recited in claim 1, wherein the electronic package is fabricated in a flip-chip configuration.

5. The electronic package as recited in claim 1, wherein the attachment piece is selected from the group consisting of a printed circuit board (PCB), a ceramic substrate, a semiconductor substrate, and a substrate.

6. The electronic package as recited in claim 1, wherein the electronic component is selected from the group of components consisting of a device, an electronic device, and integrated circuit, and integrated circuit chip.

7. An electronic package, comprising:
an electronic component having a heat producing device and a thermal distribution layer, wherein the thermal distribution layer is thermally connected to and at least partially covers the heat producing device;
an attachment piece; and
at least two attachment units, wherein each unit comprises an attachment pillar having a mating surface, a solder layer formed on the mating surface, and an attachment pad located on the attachment piece, wherein the pillar of each unit is attached to its unit attachment pad via its unit solder layer, wherein the pillar of one of the units is attached to the thermal distribution layer, wherein the pillar of each unit other than the unit having its unit pillar attached to the thermal distribution layer is otherwise attached to the electronic component, and wherein the pillar attached to the thermal distribution layer is thermally connected to the thermal distribution layer and to its unit attachment pad via its unit solder layer.

8. The electronic package as recited in claim 7, wherein at least one unit provides electrical connection between the electronic component and the attachment piece.

9. The electronic package as recited in claim 7, wherein the electronic package is fabricated in a flip-chip configuration.

10. The electronic package as recited in claim 7, wherein the pillar attached to the thermal distribution layer at least partially covers the thermal distribution layer.

11. The electronic package as recited in claim 7, wherein the pillar attached to the thermal distribution layer at least partially covers the heat producing device.

12. The electronic package as recited in claim 7, wherein the electronic component further comprises:
at least one additional heat producing device, wherein the at least one additional heat producing device is at least partially covered by the thermal distribution layer.

13. The electronic package as recited in claim 12, wherein at least one of the heat producing devices lies at least partially outside the perimeter of the pillar connected to the thermal distribution layer.

14. The electronic package as recited in claim 7, wherein the attachment piece is selected from the group consisting of a printed circuit board (PCB), a ceramic substrate, a semiconductor substrate, and a substrate.

15. The electronic package as recited in claim 7, wherein the electronic component is selected from the group of components consisting of a device, an electronic device, and integrated circuit, and integrated circuit chip.

16. A method for fabricating an electronic package, comprising:
fabricating an electronic component having a heat producing device;
adding at least two attachment pillars to the electronic component, wherein each pillar has a mating surface;
adding a solder layer to the mating surface of each of the pillars, wherein one pillar at least partially covers the heat producing device and wherein the solder layer added to the pillar at least partially covering the heat producing device is patterned to cover less than its mating surface; and
attaching the pillars to attachment pads on an attachment piece via their solder layers, wherein the pillar at least partially covering the heat producing device is thermally connected to the heat producing device and to the attachment pad to which that pillar is attached via its unit solder layer.

17. The method as recited in claim 16, wherein at least one pillar other than the pillar that at least partially covers the heat producing device has its mating surface smaller than the mating surface of the pillar that at least partially covers the heat producing device.

18. The method as recited in claim 16, wherein at least pillar provides electrical connection between the electronic component and the attachment piece.

19. A method for fabricating an electronic package, comprising:
fabricating an electronic component having a heat producing device;
adding a thermal distribution layer thermally connected to and at least partially covering the heat producing device;
adding at least two attachment pillars to the electronic component, wherein each pillar has a mating surface, wherein one of the pillars is attached to the thermal distribution layer, and wherein the pillars other than the pillar attached to the thermal distribution layer is otherwise attached to the electronic component;
adding a solder layer to the mating surface of each of the pillars; and
attaching the pillars to attachment pads on an attachment piece via their solder layers, wherein the pillar attached to the thermal distribution layer is thermally connected to the thermal distribution layer and to the attachment pad to which it is physically connected via its unit solder layer.

20. The method as recited in claim 19, wherein at least one pillar provides electrical connection between the electronic component and the attachment piece.
